(19) United States
(12) Patent Application Publication
(10) Pub. No.: US 2024/0096833 A1
(43) Pub. Date: Mar. 21, 2024

(54) SEMICONDUCTOR STRUCTURE AND METHOD FOR MANUFACTURING SAME

(71) Applicant: CHANGXIN MEMORY TECHNOLOGIES, INC., Hefei City (CN)

(72) Inventors: Yuan FANG, Hefei (CN); Yanwu WANG, Hefei (CN)

(21) Appl. No.: 18/510,864

(22) Filed: Nov. 16, 2023

Related U.S. Application Data
(63) Continuation of application No. PCT/CN2022/123990, filed on Oct. 9, 2022.

(30) Foreign Application Priority Data
Sep. 19, 2022 (CN) 202211139706.7

(51) Int. Cl. H01L 23/00; H01L 23/48; H01L 25/065

(52) U.S. Cl. CPC H01L 24/13; H01L 23/481; H01L 24/16; H01L 24/81; H01L 25/0657; H01L 2224/13015; H01L 2224/13083; H01L 2224/16145; H01L 2224/16225; H01L 2224/81801

(57) ABSTRACT

A semiconductor structure and a method for manufacturing the same are disclosed. The semiconductor structure includes a substrate, a chip stack disposed on the substrate through a plurality of first conductive structures. Each of the plurality of the first conductive structures includes a first conductive bump, and the first conductive bump includes at least one concave surface. Concave surfaces of adjacent first conductive bumps are disposed facing each other.

### CROSS-REFERENCE TO RELATED APPLICATION

The present application is a U.S. continuation application of International Application No. PCT/CN2022/123990, filed on Oct. 9, 2022, which claims priority to Chinese Patent Application No. 202211139706.7, filed on Sep. 19, 2022, and entitled “SEMICONDUCTOR STRUCTURE AND METHOD FOR MANUFACTURING SAME”. International Application No. PCT/CN2022/123990 and Chinese Patent Application No. 202211139706.7 are incorporated herein by reference in their entireties.

### TECHNICAL FIELD

The disclosure relates to the technical field of semiconductor, in particular to a semiconductor structure and a method for manufacturing the same.

### BACKGROUND

Typically, high bandwidth memory (HBM) chips may be stacked on an upper surface of a package substrate. The HBM chip may be electrically connected with the package substrate via conductive bumps. With the development of 3D package stacking technology, the demand of high bandwidth and low power consumption promotes higher chip stacking and denser through silicon via (TSV) interconnection. However, the higher the integration level of the HBM is, the larger the parasitic parameters of interconnections will be.

### SUMMARY

In view of the above, embodiments of the disclosure provide a semiconductor structure and a method for manufacturing the same.

According to the first aspect of the embodiments of the present disclosure, a semiconductor structure is provided, which includes a substrate and a chip stack.

The chip stack is disclosed on the substrate through a plurality of first conductive structures.

Each of the plurality of the first conductive structures includes a first conductive bump including at least one concave surface. Concave surfaces of adjacent first conductive bumps are disposed facing each other.

According to a second aspect of the embodiments of the present disclosure, a method for manufacturing a semiconductor structure is provided, which includes the following operations.

A substrate is provided.

A chip stack is formed, in which a plurality of first conductive structures are formed. The chip stack is disposed on the substrate through the plurality of the first conductive structures.

Each of the plurality of the first conductive structures includes a first conductive bump including at least one concave surface, and concave surfaces of adjacent first conductive bumps are disposed facing each other.

### BRIEF DESCRIPTION OF THE DRAWINGS

In order to more clearly illustrate the embodiments of the disclosure or the technical solution in the conventional technique, the drawings required in the embodiments will be briefly introduced below. Apparently, the drawings of the following description are merely some embodiments of the disclosure. For those of ordinary skill in the art, other drawings may also be obtained based on these drawings without creative efforts.

FIG. 1 is a top schematic structural diagram of first conductive structures in the related art.

FIG. 2 is a perspective diagram of the first conductive structures provided in embodiments of the disclosure.

FIG. 3 is a schematic structural diagram of the first conductive structures provided in the embodiments of the disclosure.

FIG. 4 is an enlarged view of the convex surface of the first conductive bump.

FIG. 5A and FIG. 5B are other examples of the first conductive structures provided in embodiments of the disclosure.

FIG. 6A is a schematic structural diagram of the first conductive structures provided in another embodiment of the disclosure.

FIG. 6B is a perspective diagram of the first conductive structures provided in another embodiment of the disclosure.

FIG. 7 is a schematic structural diagram of a semiconductor structure provided in embodiments of the disclosure.

FIG. 8 is a schematic diagram showing the connection between two adjacent layers of chips through first interconnects.

FIG. 9 is a flowchart of a method for manufacturing semiconductor structures provided in embodiments of the disclosure. and

FIGS. 10A to 10H are schematic structural diagrams of semiconductor structures in the manufacturing process provided in embodiments of the disclosure.

### DETAILED DESCRIPTION

Exemplary embodiments of the present disclosure will be described in more detail below with reference to the accompanying drawings. Although exemplary embodiments of the present disclosure are shown in the drawings, it should be understood that the present disclosure may be implemented in various forms and should not be limited to the specific embodiments set forth herein. These embodiments are provided so that the disclosure will be more thoroughly understood and the scope of the disclosure will be fully conveyed to those skilled in the art.

In the description hereinbelow, numerous specific details are given to provide a more thorough understanding of the disclosure. However, it will be apparent to those skilled in the art that the disclosure may be implemented without one or more of these details. In other examples, some technical features well-known in the art are not described in order to avoid confusion with the present disclosure. That is, not all of the features of actual embodiments are described herein, and well-known functions and structures are not described in detail.

In the drawings, the dimensions of layers, regions, elements and their relative dimensions may be exaggerated for clarity. The same reference numeral denotes the same element throughout the text.

It should be understood that when an element or a layer is referred to as “on”, “adjacent to”, “connected to” or “coupled to” another element or layer, it may be directly on the other element or layer, adjacent to the other element or layer, or connected to or coupled to the other element or layer, or there may be an intermediate element or layer therebetween. In contrast, when an element is described as “directly on”, “directly adjacent to”, “directly connected to” or “directly coupled to” another element or layer, there is no intermediate element or layer therebetween. It should be understood that although the terms “first”, “second”, “third” and the like may be used to describe various elements, components, regions, layers, and/or portions, these elements, components, regions, layers, and/or portions should not be limited by these terms. These terms are only used to distinguish one element, component, region, layer or portion from another element, component, region, layer or portion. Therefore, without departing from the teaching of the present disclosure, a first element, component, region, layer or portion discussed hereinafter may be expressed as a second element, component, region, layer or portion. While discussing a second element, component, region, layer or portion, it does not imply that a first element, component, region, layer or portion is necessarily present in the present disclosure.

Spatial relationship terms such as “beneath”, “below”, “lower”, “under”, “above”, or “upper” may be used herein for convenience to describe a relationship between one element or feature and another element or feature shown in the drawings. It should be understood, the spatial relationship terms tend to further include different orientations of a device in use and operation in addition to the orientations shown in the drawings. For example, if the device in the drawings is turned over, an element or feature described as being “below” or “under” or “beneath” another element will be oriented as being “above” the other element or feature. Therefore, the exemplary terms “below” and “under” may include up and down orientations. The device may also include additional orientations (e.g., rotation for 90 degrees or other orientations), and the spatial terms used herein are interpreted accordingly.

The terms used herein are intended to describe specific embodiments only and are not to be a limitation to the present disclosure. As used herein, the singular forms “a”, “an”, and “the/said” are intended to include the plural forms as well, unless the context clearly dictates otherwise. It should be further understood that when terms “consist of” and/or “comprise/include” used in the specification mean that the stated features, integers, steps, operations, elements and/or components are present, but the presence or addition of one or more of other features, integers, steps, operations, elements, components and/or combinations is not excluded. When used herein, the term “and/or” includes any of the listed items and all combinations thereof.

In order to thoroughly understand the present disclosure, detailed operations and structures will be set forth in the following description in order to illustrate the technical solution of the present disclosure. Preferred embodiments of the present disclosure are described in detail below. However, the present disclosure may have other embodiments in addition to these detailed descriptions.

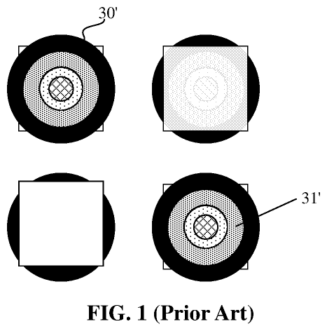

In the related art, as shown in FIG. 1, the first conductive bump 31′ in the first conductive structure 30′ is of a circular shape, and thus the RLC parasitic parameter of the first conductive bump 31′ of the circular shape is larger, which has increasing impacts on the integrity of the signal and further affects the performance of the memory.

A semiconductor structure is provided in an embodiment of the disclosure.

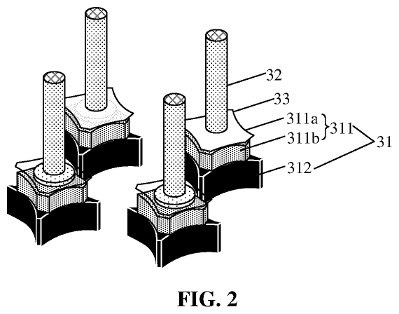

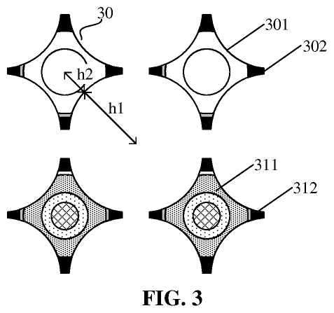

FIG. 2 is a perspective diagram of the first conductive structures provided in an embodiment of the disclosure; and FIG. 3 is a schematic structural diagram of the first conductive structures provided in the embodiments of the disclosure.

As shown in FIGS. 2 and 3, the first conductive structure 30 includes a first conductive bump 31. The first conductive bump 31 includes at least one concave surface 301. Concave surfaces 301 of the adjacent first conductive bumps 31 are disposed facing each other.

In the embodiment of the disclosure, when a signal passes through one first conductive bump 31, the parasitic RLC is introduced into other first conductive bumps 31 around this one first conductive bump due to the edge field radiation effect which is inversely proportional to the distance. The farther the distance is, the weaker the edge field radiation effect is. Therefore, by arranging the concave surfaces of adjacent first conductive bumps 31 facing each other, the overlapping range of the edge field in space is weakened, thereby reducing parasitic parameters caused by the edge field radiation. At the same time, the first conductive bump 31 is disposed with including at least one concave surface, so that the volume of the first conductive bump 31 is reduced, thereby reducing the parasitic capacitance of the first conductive bump itself.

In an embodiment, a plurality of the first conductive structures 30 are arranged in a quadrilateral arrangement. For multiple first conductive structures 30 in quadrilateral arrangement, the concave surfaces 301 of the two first conductive bumps 31 of first conductive structures 30 at diagonal positions are disposed facing each other.

In the embodiment, the concave surfaces of the first conductive bumps at diagonal positions are disposed facing each other, so that the distance between the first conductive bumps is increased, which reduces the edge field between the first conductive bumps, and further reduces the RLC parasitic parameters.

In some embodiments, as shown in FIG. 3, the first conductive structures 30 are arranged in a regular quadrilateral arrangement. That is, four conductive structures are in a rectangle. In other embodiments, four first conductive structures may also be formed in a diamond or trapezoidal shape.

In an embodiment, referring to FIG. 3, the first conductive bump 31 further includes at least one convex surface 302 adjacent to the concave surface 301. The convex surface is provided to facilitate the subsequent welding of the first conductive structures, thereby ensuring the welding quality of the first conductive bump 31.

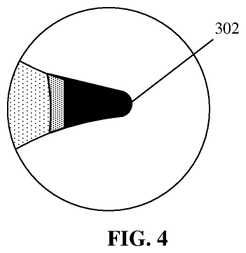

FIG. 4 is an enlarged view of the convex surface of the first conductive bump. As shown in FIG. 4, the convex surface 302 is of an outward protruding shape.

As shown in FIG. 3, in the plurality of the first conductive structures 30 in the quadrilateral arrangement, the first conductive bump 31 of each of the plurality of the first conductive structures 30 includes a plurality of concave surfaces 301. A convex surface 302 is arranged between two adjacent ones of the concave surfaces 301. The area of the concave surface 301 is larger than the area of the convex surface 302.

The concave surface is arranged to increase the distance between two first conductive bumps, and then to reduce the RLC parasitic parameters. Therefore, the area of the concave surface is arranged larger, which is convenient for reducing the parasitic parameters. The convex surface is arranged to facilitate welding and ensure welding quality, so there is no need to arrange the area of the convex surface too large, as long as it is convenient for welding.

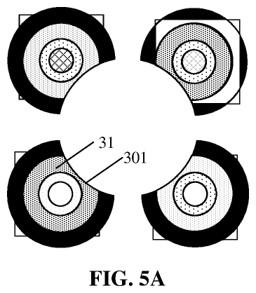

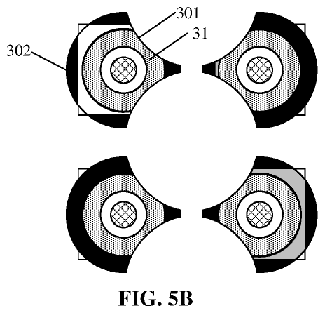

In some embodiments, as shown in FIG. 5A, the first conductive bump 31 includes one concave surface 301 disposed facing the center position in the quadrilateral arrangement. In the embodiment, each first conductive bump is provided with only one concave surface, but this one concave surface is disposed facing the concave surfaces of other first conductive bumps. Therefore, the parasitic parameters can be reduced to a certain extent, while reducing process steps and manufacturing cost.

In other embodiments, as shown in FIG. 5B, the first conductive bump 31 includes two concave surfaces 301. The concave surfaces 301 of the adjacent first conductive bumps 31 are disposed facing each other. In the embodiment, two concave surfaces are arranged, so that the parasitic parameters can be further reduced. Meanwhile, as only two concave surfaces are arranged, the area of the convex surface is relatively large, thus increasing the welding area and ensuring the welding quality.

In other embodiments, as shown in FIG. 3, the first conductive bump 31 of each of the first conductive structures 30 includes a plurality of concave surfaces 301.

In an embodiment, as shown in FIG. 3, a distance from the diagonal intersection point of the quadrilateral arrangement to the concave surface 301 of each of the first conductive bumps 31 is defined as a first distance h1. A distance from the concave surface 301 of each of the first conductive bumps 31 to a center of the first conductive bump 31 is defined as a second distance h2. A a ratio of the first distance h1 to the second distance h2 ranges from 5:3 to 5:2.

If the ratio of the first distance to the second distance is set too large, it means that the concave surface of the first conductive bump is too close to the center of the first conductive bump, which will lead to the area of the first conductive bump being too small and thus affect the conductive performance of the first conductive bump. If the ratio of the first distance to the second distance is set too small, it means that the concave surface of the first conductive bump is close to the diagonal intersection point, which will reduce the distance between two adjacent first conductive bumps, and thus increase the parasitic parameters. Therefore, the ratio of the first distance to the second distance is set in the range from 5:3 to 5:2, which not only ensures the conductivity of the first conductive bump, but also reduces the parasitic parameters.

In an embodiment, as shown in FIG. 2, each of the plurality of the first conductive structures 30 further includes a first through silicon via 32 and a first test pad 33. The first through silicon via 32 is disposed on the first conductive bump 31, and the first test pad 33 is disposed between the first through silicon via 32 and the first conductive bump 31.

The first through silicon via and the first conductive bump ensure the subsequent electrical connection between the substrate and the chip stack. The first test pad can be used for testing functions.

The conductive material in the first through silicon via 32 includes, but is not limited to, Cu. The conductive material is wrapped with an insulating material which includes, but is not limited to, SiO₂. The material of the first test pad 33 includes, but is not limited to Al.

In an embodiment, as shown in FIG. 3, the first conductive bump 31 includes a first solder pad 311 and a first solder ball 312. The first solder pad 311 is disposed on the first solder ball 312. The orthographic projection of the first solder pad 311 on the substrate is disposed within the orthographic projection of the first solder ball 312 on the substrate.

As shown in FIG. 2, the first solder pad 311 includes a first sub-solder pad 311a and a second sub-solder pad 311b. The first sub-solder pad is disposed on the second sub-solder pad 311b. The volume of the first sub-solder pad 311a is smaller than the volume of the second sub-solder pad 311b.

In some embodiments, during forming the first sub-solder pad 311a and the second sub-solder pad 311b, an insulating layer is first formed on the first test pad, and covers the first test pad. Then the insulating layer is exposed to light to form an opening on the first test pad. That is, the depth of the opening is equal to the thickness of the insulating layer on the first test pad, and the width of the opening may be smaller than the width of the first test pad, so that the volume of the first sub-solder pad 311a is smaller and the volume of the second sub-solder pad 311b is larger. If an opening with a larger width is to be formed during exposure, for example, the width of the opening is larger than the width of the first test pad, the depth of the opening will be increased, and the exposure will be affected by diffuse reflection, resulting in an abnormal exposure pattern. Therefore, the first sub-solder pad 311a having a smaller volume is formed and the second sub-solder pad 311b having a larger volume is formed. It should be noted that the first sub-solder pad 311a and the second sub-solder pad 311b may be formed simultaneously.

In some embodiments, when the first conductive bump 31 is of an octagonal shape, eight concave surfaces may also be provided on the first conductive bump 31, so that the parasitic parameters generated by the first conductive bump 31 can be reduced.

Table 1 shows simulation data of the first conductive structures in the quadrilateral arrangement in the related art, while table 2 shows simulation data of the first conductive structures in the quadrilateral arrangement in the embodiment of the present disclosure. It should be explained that in the related art, the shape of the first conductive bump of each of the first conductive structures is of a circular shape as shown in FIG. 1.

TABLE 1

| | R(mΩ) | L(pH) | C(fF) |
|---|---|---|---|
| First conductive structure 1 | 155.15 | 36.02 | 52.26 |
| First conductive structure 2 | 155.13 | 36.02 | 52.27 |
| First conductive structure 3 | 155.12 | 36.02 | 52.27 |
| First conductive structure 4 | 155.11 | 36.02 | 52.27 |

TABLE 2

| | R(mΩ) | L(pH) | C(fF) |
|---|---|---|---|
| First conductive structure 1 | 137.28 | 35.2 | 48.12 |
| First conductive structure 2 | 137.27 | 35.2 | 48.12 |
| First conductive structure 3 | 137.26 | 35.2 | 48.11 |
| First conductive structure 4 | 137.24 | 35.2 | 48.15 |

As can be seen from the comparison of Table 1 and Table 2, the parasitic resistance R, parasitic inductance L and parasitic capacitance C of the first conductive structure in the embodiments of the present disclosure are reduced by 11.52%, 2.28% and 7.96%, respectively. Therefore, the first conductive structure provided in the embodiments of the present disclosure can reduce the parasitic parameters and improve the device performance.

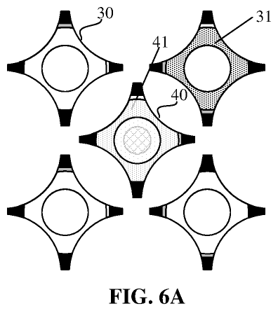

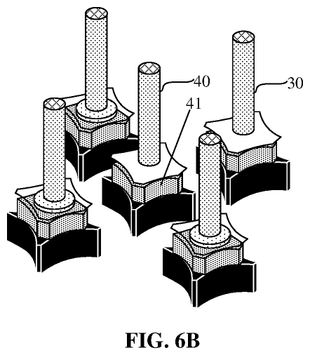

In an embodiment, as shown in FIGS. 6A and 6B, the semiconductor structure further includes a second conductive structure 40 disposed at a diagonal intersection point of the quadrilateral arrangement. The second conductive structure 40 includes a second conductive bump 41, and the second conductive bump 41 includes at least one concave surface.

The second conductive structure 40 is arranged at the central of the first conductive structures 30 arranged in the quadrilateral arrangement, and the first conductive structures 30 are signal conductive structures. Specifically, the first conductive structures 30 transmit a high voltage signal, while the second conductive structure 40 is a grounded conductive structure and transmits a low voltage signal. As the signal will be transmitted to the nearby ground or a power source as a return path during transmission, the capacity of electromagnetic flow to the grounded conductive structure, i.e. the second conductive structure close to the first conductive structures, is increased, and the capacity to the first conductive structures is relatively reduced, thereby effectively reducing the edge field effect and reducing the RLC parasitic parameters in the return path section.

In an embodiment, each concave surface of the second conductive bump 41 is disposed facing one of the concave surfaces of the first conductive bump 31 adjacent thereto. When the concave surface of the second conductive bump is disposed facing the concave surface of the first conductive bump, the distance between the first conductive bump and the second conductive bump is increased, which will reduce the crosstalk therebetween.

Table 3 shows simulation data for the first conductive structures of each quadrilateral arrangement when the second conductive structure is arranged.

TABLE 3

| | R(mΩ) | L(pH) | C(fF) |
|---|---|---|---|
| First conductive structure 1 | 136.91 | 35.02 | 38.76 |
| First conductive structure 2 | 136.86 | 35.01 | 38.75 |
| First conductive structure 3 | 136.86 | 35.00 | 38.70 |
| First conductive structure 4 | 136.85 | 35.00 | 38.71 |

As can be seen from the comparison of Table 2 and Table 3, the parasitic resistance R, parasitic inductance L and parasitic capacitance C of the first conductive structures when the second conductive structure is arranged, are reduced by 0.3%, 0.57% and 19.61%, respectively. It can be seen that the parasitic parameters, especially the parasitic capacitance, can be reduced by arranging the second conductive structure, and then the device performance can be improved.

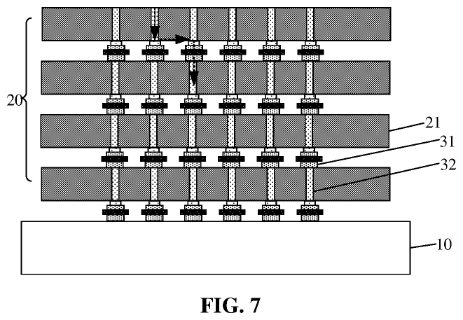

In an embodiment, as shown in FIG. 7, the first conductive structures can be used in a multi-chip stacked structure for electrically connecting adjacent chips and improving the connection mode, so as to further reduce the RLC parasitic parameters.

Specifically, as shown in FIG. 7, the semiconductor structure further includes a substrate 10; and a chip stack 20 disposed on the substrate 10 through a plurality of first conductive structures 30.

In an embodiment, the substrate 10 may be a printed circuit board (PCB) or a redistributed substrate or a logic chip.

The substrate may include a base (not shown) and an upper insulating dielectric layer and a lower insulating dielectric layer (not shown) on an upper surface and a lower surface of the base, respectively.

The base may be silicon base, germanium base, silicon germanium base, silicon carbide base, SOI (Silicon On Insulator) base, GOI (Germanium On Insulator) base, or the like; also may be a base including other element semiconductor or compound semiconductor, such as a glass base or a Group III-V compound base (such as gallium nitride base or gallium arsenide base, or the like); further may be a laminated structure, such as Si/SiGe, or the like; and may be other epitaxial structures, such as SGOI (Germanium On Insulator), or the like.

The upper insulating dielectric layer and the lower insulating dielectric layer may be solder resist layers, for example, the materials of the upper insulating dielectric layer and the lower insulating dielectric layer may be green paint.

In an embodiment, adjacent layers of chips 21 can also be connected through the first conductive bump 31 and the first through silicon via 32. Next, the connection mode between adjacent chips in the chip stack shown in FIG. 7 will be further described.

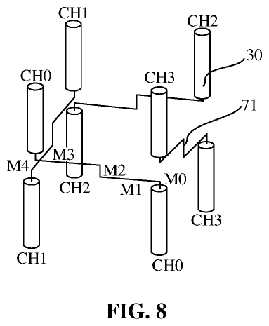

In an embodiment, as shown in FIGS. 7 and 8, the chip stack 20 includes a plurality of chips 21 sequentially stacked. Each of the plurality of the chips 21 includes n first conductive structures 30, where n is greater than or equal to 2.

Projections of the first through silicon vias 32 of corresponding first conductive structures 30 in two adjacent layers of the chips 21 are non-overlapping in a projection along a direction perpendicular to the plane of the substrate 10.

In the embodiment of the disclosure, the projections of the first through silicon vias of the corresponding first conductive structures in two adjacent layers of the chips are non-overlapping, indicating that the corresponding first through silicon vias in the two adjacent layers of the chips are arranged at a certain angle. By this way, the same signal spirals up in the structure formed by stacking a plurality of chips, which can reduce the crosstalk between different signals, while optimizing the spatial structure, and forming the memory with higher bandwidth.

In an embodiment, as shown in FIG. 8, the semiconductor structure further includes first interconnects 71 through which corresponding first conductive structures 30 in two adjacent layers of the chips 21 are connected. By forming the first interconnects 71 in the chips, the connection when the first conductive structures 30 are helically arranged is realized, which ensures the normal transmission of signals.

Specifically, as shown in FIG. 8, for example, multiple first conductive structures 30, namely CH0, CH1, CH2 and CH3, may be included in each layer of the chip. The corresponding CH0(s) in each layer of the chips is connected through the first interconnect 71 and spirals up at a certain angle, while CH1(s), CH2(s) and CH3(s) are likewise connected through the first interconnects 71 and spiral up at a certain angle, respectively. The first interconnects connecting two corresponding first conductive structures in the same layer are deflected at a certain angle, which reduces the opposite area of the first interconnects to each other, and thus reduce the crosstalk between the first interconnects.

In an embodiment, one end of each of the first interconnects is connected to the first through silicon via, and the other end of the first interconnect is connected to the first conductive bump.

The first interconnects are metal lines, as shown in FIG. 8, including metal lines M0 to M4.

As shown in FIG. 8, one end of one first interconnects 71 is M0, which is connected to the first through silicon via or the first conductive bump of one first conductive structure in one layer of the chips, and the other end M4 is connected to the first through silicon bump or the first through silicon via of the corresponding first conductive structure in the adjacent layer of the chips. That is, one end is connected to the first through silicon via, the other end is connected to the first conductive bump, and vice versa. Herein, M0 and M4 are connected by M1, M2 and M3.

It should be explained that, in FIG. 8, the end face of CH0 in the lower layer of the chips connected by M0 and the end face of the CH0 in the upper layer of the chips connected by M4 should be on the same horizontal plane, i.e., the first interconnects should be parallel to the plane of the chip. Specifically, referring to FIG. 7, signal is transmitted along the direction of the arrow from the first conductive structure in one layer of the chips to the corresponding first conductive structure in an adjacent layer of the chips, in which the first interconnects are disposed at the position indicated by the arrow parallel to the plane of the chip.

As shown in FIG. 8, the first conductive structures 30 (e.g. CH0 and CH1) in the semiconductor structure are spirally arranged in the stacking direction instead of vertically arranged. Therefore, the distance between two adjacent layers of the chips, of the same first conductive structure 30 (e.g. CH0) is increased. If the first conductive structures 30 (such as CH0 and CH1) in the semiconductor structure are vertically arranged, all of the first conductive structures 30 in the chips will generate the signal crosstalk due to the edge field effect. At the same time, as the first conductive structures 30 are vertically arranged, that is, the distance between two adjacent layers of the chips, of the same first conductive structure 30 are relatively close, which will cause the superposition of the crosstalk effects.

Moreover, the superposition of the crosstalk effects increases with the length of the signal formed by the first conductive structures 30, which will eventually lead to signal distortion in the top layer of the chips.

However, in this embodiment, since the first conductive structures 30 (e.g. CH0 and CH1) are helically arranged, that is, the distance between two adjacent layers of the chips, of the same first conductive structure 30 (e.g. CH0) is increased, when two different signals cross-talk in the same chip, the crosstalk effect will not be superimposed on another chip, thereby improving the influence of crosstalk on signals.

As shown in FIG. 8 the first conductive structure 30 may be a through silicon via structure and CH0 and CH1 may represent different through silicon vias, i.e. through silicon vias that transmit different signals.

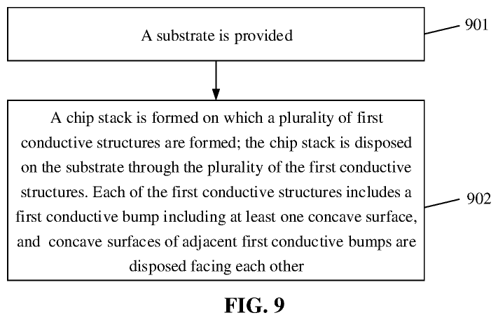

Embodiments of the disclosure further provide a method for manufacturing a semiconductor structure. In particular, with reference to FIG. 9, as shown in the figure, the method includes the following operations.

S901: a substrate is provided;

S902: a chip stack is formed. A plurality of first conductive structures are formed on the chip stack. The chip stack is disposed on the substrate through the plurality of the first conductive structures. Each of the plurality of the first conductive structures includes a first conductive bump, and the first conductive bump includes at least one concave surface.

Concave surfaces of the adjacent first conductive bumps are disposed facing each other.

The method for manufacturing the semiconductor structure provided in the embodiments of the disclosure will be described in further detail below in combination with specific embodiments.

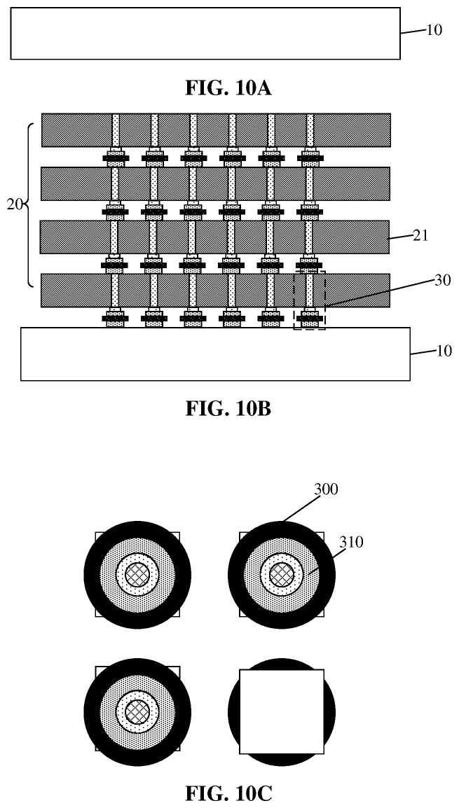

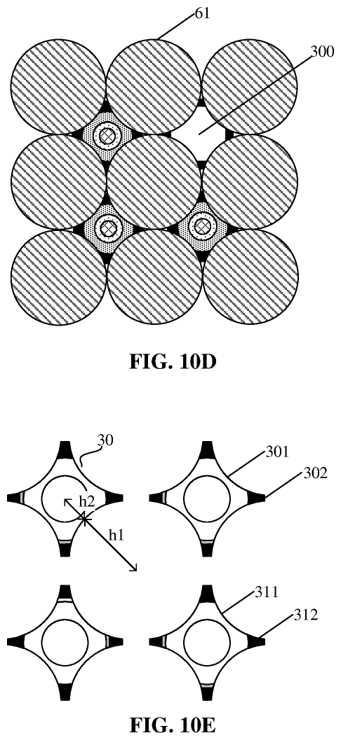

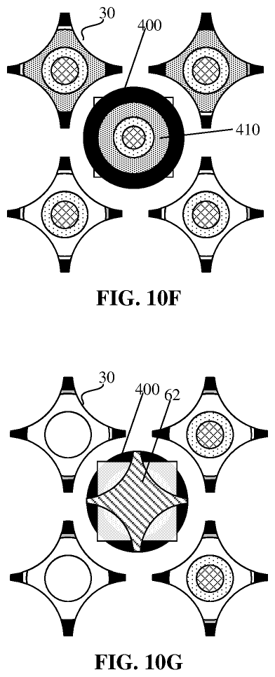

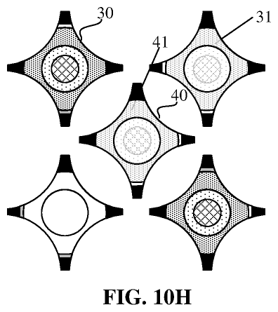

FIG. 10A to FIG. 10H are schematic structural diagrams of a semiconductor structure in the manufacturing process provided in embodiments of the disclosure.

First, referring to FIG. 10A, S901 is performed, in which the substrate 10 is provided.

In an embodiment, the substrate 10 may be a printed circuit board (PCB) or a redistributed substrate or a logic chip.

The substrate may include a base (not shown) and an upper insulating dielectric layer and a lower insulating dielectric layer (not shown) on an upper surface and a lower surface of the base, respectively.

The base may be silicon base, germanium base, silicon germanium base, silicon carbide base, SOI (Silicon On Insulator) base, GOI (Germanium On Insulator) base, or the like; also may be a base including other element semiconductor or compound semiconductor, such as a glass base or a Group III-V compound base (such as gallium nitride base or gallium arsenide base, or the like); further may be a laminated structure, such as Si/SiGe, or the like; and may be other epitaxial structures, such as SGOI (Germanium On Insulator), or the like.

The upper insulating dielectric layer and the lower insulating dielectric layer may be solder resist layers, for example, the materials of the upper insulating dielectric layer and the lower insulating dielectric layer may be green paint.

Next, referring to FIG. 10B to FIG. 10E, S902 is performed, in which the chip stack 20 is formed. On the chip stack 20, a plurality of first conductive structures 30 are formed. The chip stack 20 is disposed on the substrate 10 through the plurality of the first conductive structures 30. Each of the plurality of the first conductive structures 30 includes a first conductive bump 31, and the first conductive bump 31 includes at least one concave surface 301. Concave surfaces 301 on the adjacent first conductive bumps 31 are disposed facing each other.

Referring first to FIG. 10B, the chip stack 20 is formed on the substrate 10, and includes a plurality of chips 21 sequentially stacked.

Next, the process for manufacturing the first conductive structures will be described in detail with referring to FIG. 10C to FIG. 10E.

The plurality of the first conductive structures 30 are formed by the following operations.

Initial first conductive structures 300 are formed, in which each of the initial first conductive structures 30 includes an initial first conductive bump 310 of a circular shape of.

At least one first mask layer 61 is formed on the initial first conductive bump 310, in which the first mask layer covers part of a periphery of the initial first conductive bump 310.

Part covered by the first mask layer 61, of the initial first conductive bump 310 is removed by etching to form the first conductive structure 30.

In an embodiment, the first mask layer 61 is of a circular shape such that the first conductive bump formed by removing part of the initial first conductive bump 310 includes at least one concave surface.

It should be understood that, the first mask layer may also be of other arc-shaped structures.

In an embodiment, a plurality of the first conductive structures 30 are arranged in a quadrilateral arrangement. For the plurality of the first conductive structures 30 in the quadrilateral arrangement, the concave surfaces of the first conductive bumps 31 of the first conductive structures 30 at diagonal positions of are disposed facing each other.

In the embodiment, the concave surfaces of the first conductive bumps at diagonal positions are disposed facing each other, so that the distance between the first conductive bumps is increased, which reduces the edge field between the first conductive bumps, and further reduces the RLC parasitic parameters.

In some embodiments, as shown in FIG. 10E, the first conductive structures 30 are in a regular quadrilateral arrangement. That is, four conductive structures are in a rectangle. In other embodiments, four of the first conductive structures may also be formed in a diamond or trapezoidal shape.

In an embodiment, referring to FIG. 10E, the first conductive bump 31 further includes at least one convex surface 302, and the convex surface 302 is arranged adjacent to the concave surface 301. The convex surface is provided to facilitate the subsequent welding of the first conductive structures, thereby ensuring the welding quality of the first conductive bump 31.

As shown in FIG. 10E, in the plurality of the first conductive structures 30 in the quadrilateral arrangement, the first conductive bump 31 of each of the plurality of the first conductive structures 30 includes a plurality of concave surfaces 301. A convex surface 302 is arranged between two adjacent ones of the concave surfaces 301. The area of the concave surface 301 is larger than the area of the convex surface 302.

The concave surface is arranged to increase the distance between two first conductive bumps, and then to reduce the RLC parasitic parameters. Therefore, the area of the concave surface is arranged larger, which is convenient for reducing the parasitic parameters. The convex surface is arranged to facilitate welding, so there is no need to arrange the area of the convex surface too large, as long as it is convenient for welding.

In an embodiment, as shown in FIG. 10E, a distance from the diagonal intersection point of the quadrilateral arrangement to the concave surface 301 of the first conductive bump 31 is defined as a first distance h1, a distance from the concave surface 301 of the first conductive bump 31 to the center of the first conductive bump 31 is defined as a second distance h2, and a ratio of the first distance h1 to the second distance h2 ranges from 5:3 to 5:2.

If the ratio of the first distance to the second distance is set too large, it means that the concave surface of the first conductive bump is too close to the center of the first conductive bump, which will lead to the area of the first conductive bump being too small and thus affect the conductive performance of the first conductive bump. If the ratio of the first distance to the second distance is set too small, it means that the concave surface of the first conductive bump is close to the diagonal intersection point, which will reduce the distance between two adjacent first conductive bumps, and thus increase the parasitic parameters. Therefore, the ratio of the first distance to the second distance is set in a range from 5:3 to 5:2, which not only ensures the conductivity of the first conductive bump, but also reduces the parasitic parameters.

In an embodiment, as shown in FIG. 2, each of the plurality of the first conductive structures 30 further includes a first through silicon via 32 and a first test pad 33. The first through silicon via 32 is disposed on the first conductive bump 31, and the first test pad 33 is disposed between the first through silicon via 32 and the first conductive bump 31.

The first through silicon via and the first conductive bump ensure the subsequent electrical connection between the substrate and the chip stack. The first test pad can be used for testing functions.

The conductive material in the first through silicon via 32 includes, but is not limited to, Cu. The conductive material is wrapped with an insulating material which includes, but is not limited to, SiO₂. The material of the first test pad 33 includes, but is not limited to Al.

In an embodiment, as shown in FIG. 10E, the first conductive bump 31 includes a first solder pad 311 and a first solder ball 312. The first solder pad 311 is disposed on the first solder ball 312. The orthographic projection of the first solder pad 311 on the substrate 10 is disposed within the orthographic projection of the first solder ball 312 on the substrate 10.

As shown in FIG. 2, the first solder pad 311 includes a first sub-solder pad 311a and a second sub-solder pad 311b. The first sub-solder pad is disposed on the second sub-solder pad 311b. The volume of the first sub-solder pad 311a is smaller than the volume of the second sub-solder pad 311b.

The first sub-solder pad is connected with the first test pad, so that the contact area with the first test pad can be reduced due to the small volume of the first sub-solder pad, thereby reducing the contact resistance.

Next, referring to FIG. 10F to FIG. 10H, the method further includes the following operations. A second conductive structure 40 is formed at a diagonal intersection point of the quadrilateral arrangement. The second conductive structure 40 includes a second conductive bump 41, and the second conductive bump 41 includes at least one concave surface.

In an embodiment, the formation of the second conductive structure 40 includes the following operations.

An initial second conductive structure 400 is formed at a diagonal intersection point of the quadrilateral arrangement. The initial second conductive structure 400 includes an initial second conductive bump 410 of a circular shape.

A second mask layer 62 is formed at a central position of the initial second conductive bump 410. The second mask layer 62 includes at least one concave surface.

Part not covered by the second mask layer 62, of the initial second conductive bump 410 is removed by etching to form the second conductive structure 40.

The second conductive structure 40 is arranged at the central of the first conductive structures 30 in the quadrilateral arrangement, and the first conductive structures 30 are signal conductive structures. Specifically, the first conductive structures 30 transmit a high voltage signal, while the second conductive structure 40 is a grounded conductive structure and transmits a low voltage signal. As the signal will be transmitted to the nearby ground or a power source as a return path during transmission, the capacity of electromagnetic flow to the grounded conductive structure, i.e. the second conductive structure close to the first conductive structures, is increased, and the capacity to the first conductive structures is relatively reduced, thereby effectively reducing the edge field effect and reducing the RLC parasitic parameters in the return path section.

In an embodiment, each concave surface of the second conductive bump 41 is disposed facing one of the concave surfaces of the first conductive bump 31 adjacent thereto. When the concave surface of the second conductive bump is disposed facing the concave surface of the first conductive bump, the distance between the first conductive bump and the second conductive bump is increased, which will reduce the crosstalk therebetween.

The description above only refers to preferred embodiments of the disclosure, and is not intended to limit the protection scope of the present disclosure. Any modification, equivalent replacement or improvement made within the spirit and principle of the disclosure falls within the protection scope of the disclosure.

1. A semiconductor structure, comprising:
a substrate; and
a chip stack disposed on the substrate through a plurality of first conductive structures;
wherein each of the plurality of the first conductive structures comprises a first conductive bump comprising at least one concave surface, and concave surfaces of adjacent first conductive bumps are disposed facing each other.

2. The semiconductor structure of claim 1, wherein a plurality of the first conductive structures are in a quadrilateral arrangement, and
for the plurality of the first conductive structures in the quadrilateral arrangement, the concave surfaces of the first conductive bumps of the first conductive structures at diagonal positions are disposed facing each other.

3. The semiconductor structure of claim 2, wherein,
a distance from a diagonal intersection point of the quadrilateral arrangement to the concave surface of each of the first conductive bumps is defined as a first distance; a distance from the concave surface of each of the first conductive bumps to a center of the first conductive bump is defined as a second distance; and a ratio of the first distance to the second distance ranges from 5:3 to 5:2.

4. The semiconductor structure of claim 2, wherein,
the first conductive bump further comprises at least one convex surface arranged adjacent to the concave surface.

5. The semiconductor structure according to claim 4, wherein,
each of the first conductive bumps comprises a plurality of concave surfaces; a convex surface is arranged between two adjacent ones of the plurality of the concave surfaces; and an area of each of the concave surfaces is larger than an area of the convex surface.

6. The semiconductor structure of claim 1, wherein,
each of the plurality of the first conductive structures further comprises a first through silicon via disposed on the first conductive bump and a first test pad disposed between the first through silicon via and the first conductive bump.

7. The semiconductor structure of claim 1, wherein,
the first conductive bump comprises a first solder ball and a first solder pad disposed on the first solder ball;
wherein an orthographic projection of the first solder pad on the substrate is in an orthographic projection of the first solder ball on the substrate.

8. The semiconductor structure of claim 7, wherein,
the first solder pad comprises a first sub-solder pad and a second sub-solder pad, the first sub-solder pad being disposed on the second sub-solder pad;
wherein a volume of the first sub-solder pad is smaller than a volume of the second sub-solder pad.

9. The semiconductor structure of claim 6, wherein,
the chip stack comprises a plurality of chips sequentially stacked, each of the plurality of the chips comprises n first conductive structures, n being greater than or equal to 2;
projections of first through silicon vias of corresponding first conductive structures in two adjacent layers of the chips are non-overlapping in a projection along a direction perpendicular to a plane of the substrate.

10. The semiconductor structure of claim 2, wherein the semiconductor structure further comprises:
a second conductive structure, disposed at a diagonal intersection point of the quadrilateral arrangement, and comprising a second conductive bump; wherein the second conductive bump comprises at least one concave surface.

11. The semiconductor structure of claim 10, wherein,
each concave surface of the second conductive bump is disposed facing one concave surface of the first conductive bump adjacent to the second conductive bump.

12. The semiconductor structure of claim 10, wherein,
each of the plurality of the first conductive structures is a signal conductive structure, and the second conductive structure is a grounded conductive structure.

13. A method for manufacturing a semiconductor structure, comprising:
providing a substrate; and
forming a chip stack, wherein on the chip stack, a plurality of first conductive structures are formed, the chip stack is disposed on the substrate through the plurality of the first conductive structures;
wherein, each of the plurality of the first conductive structures comprises a first conductive bump comprising at least one concave surface, and concave surfaces of adjacent first conductive bumps are disposed facing each other.

14. The method of claim 13, wherein, the step of forming a plurality of the first conductive structures comprises:
forming initial first conductive structures, wherein each of the initial first conductive structures comprise an initial first conductive bump of a circular shape;
forming at least one first mask layer on each of the initial first conductive bumps, wherein the first mask layer covers part of a periphery of the initial first conductive bump; and
removing part covered by the first mask layer of the initial first conductive bumps by etching to form the plurality of the first conductive structure.

15. The method of claim 13, wherein,
a plurality of the first conductive structures are in a quadrilateral arrangement, and for the plurality of the first conductive structures in the quadrilateral arrangement, the concave surfaces of the first conductive bumps of the first conductive structures at diagonal positions are disposed facing each other.

16. The method of claim 15, further comprising:
forming a second conductive structure at a diagonal intersection point of each quadrilateral arrangement, wherein the second conductive structure comprises a second conductive bump comprising at least one concave surface.

17. The method of claim 16, wherein the step of forming a second conductive structure comprises:
forming an initial second conductive structure at the diagonal intersection point of the quadrilateral arrangement, wherein the initial second conductive structure comprises an initial second conductive bump of a circular shape;
forming a second mask layer at a central of the initial second conductive bump, wherein the second mask layer comprises at least one concave surface; and
removing part not covered by the second mask layer of the initial second conductive bump by etching to form the second conductive structure.
